(19) United States
(12) Patent Application Publication
(10) Pub. No.: US 2026/0129967 A1
(43) Pub. Date: May 7, 2026

(54) LOW CAPACITANCE AND MULTI-THRESHOLD VOLTAGE NANOSHEET DEVICE

(71) Applicant: International Business Machines Corporation, Armonk, NY (US)

(72) Inventors: Xiaoli He, Clifton Park, NY (US); Ruilong Xie, Niskayuna, NY (US); Takashi Ando, Eastchester, NY (US); Kishwar Mashooq, Albany, NY (US); Julien Frougier, Albany, NY (US)

(21) Appl. No.: 18/940,358

(22) Filed: Nov. 7, 2024

(51) Int. Cl. H01L 27/092; H01L 21/8238; H01L 29/06; H01L 29/423; H01L 29/49; H01L 29/66; H01L 29/775; H01L 29/786

(52) U.S. Cl. CPC H10D 84/856; H10D 30/014; H10D 30/43; H10D 30/6735; H10D 30/6739; H10D 30/6757; H10D 62/121; H10D 64/017; H10D 84/0167; H10D 84/0181; H10D 84/038

(57) ABSTRACT

A semiconductor device including nanosheets transistors that have low capacitance and different threshold voltages is provided. The different threshold voltage are obtained using different shaped semiconductor channel material nanosheets and, in some embodiments, by providing different dopant concentrations to the high-k gate dielectric layers of the nanosheet transistors.

### BACKGROUND

The present application relates to semiconductor technology, and more particularly to a semiconductor device including nanosheets transistors that have low capacitance and different threshold voltages.

The use of non-planar semiconductor transistors is the next step in the evolution of complementary metal oxide semiconductor (CMOS) devices. One type of non-planar semiconductor transistor that has been touted as a viable option beyond the 7 nm technology node is a nanosheet transistor. By “nanosheet transistor” it is meant that a device contains one or more semiconductor channel material nanosheets that are stacked one over the other, in which a gate structure is formed in a wrap-around manner around a suspended portion of the one or more semiconductor channel material nanosheets. Due to this wrap around nature, nanosheet transistors are oftentimes referred to as a gate-all-around (GAA) transistors. Nanosheet transistors provide considerable scaling with high drive current capability. Further, nanosheet transistors provide a larger drive current for a given footprint compared to finFET technology.

### SUMMARY

A semiconductor device including nanosheets transistors that have low capacitance and different threshold voltages is provided. The different threshold voltage are obtained using different shaped semiconductor channel material nanosheets and, in some embodiments, by providing different dopant concentrations to the high-k gate dielectric layers of the nanosheet transistors.

In one embodiment of the present application, the semiconductor device includes a first nanosheet transistor including a first nanosheet stack of semiconductor channel material nanosheets having a first thickness (i.e., Tsus1) located beneath a suspended portion of each of the semiconductor channel material nanosheets, and a first gate structure including a first metal doped high-k gate dielectric layer having a first metal dopant concentration wrapped around the suspended portion of each first semiconductor channel material nanosheet. The semiconductor device further includes a second nanosheet transistor that includes a second nanosheet stack of dog-bone shaped nanosheets having a second thickness (i.e., Tsus2) located beneath a suspended portion of each of the dog-bone shaped nanosheets, and a second gate structure including a second metal doped high-k gate dielectric layer having a second metal dopant concentration wrapped around the suspended portion of each of the dog-bone shaped nanosheets. In accordance with the present application, the second thickness is greater than the first thickness.

In another embodiment of the present application, the semiconductor device includes a first nanosheet transistor having a first threshold voltage Vt1, and including a first high-k gate dielectric layer having a first metal doping concentration C1; a second nanosheet transistor having a second threshold voltage Vt2, and including a second high-k gate dielectric layer having a second metal doping concentration C2; a third nanosheet transistor having a third threshold voltage Vt3, and including a third high-k gate dielectric layer having a third metal doping concentration C3; and a fourth nanosheet transistor having a fourth threshold voltage Vt4, and including a fourth high-k gate dielectric layer having a fourth metal doping concentration C4. In this embodiment of the present application, the first nanosheet transistor and the third nanosheet transistor further include a first nanosheet stack of semiconductor channel material nanosheets having a first thickness located beneath a suspended portion of each of the semiconductor channel material nanosheets, and the second nanosheet transistor and the fourth nanosheet transistor further include a second nanosheet stack of dog-bone shaped nanosheets having a second thickness located beneath a suspended portion of each of the dog-bone shaped nanosheets in which the second thickness is greater than the first thickness, and C1=C2, C3=C4, and C1 and 2 is greater than C3 and C4. In this embodiment of the present disclosure, Vt1<Vt2<Vt3<Vt4.

### BRIEF DESCRIPTION OF THE DRAWINGS

FIG. 1 is a top down view illustrating a device layout that can be used in accordance with an embodiment of the present application.

FIG. 2A is a cross sectional view of a first exemplary structure along cut X-X shown in FIG. 1 that can be used in forming a low threshold voltage semiconductor device, the first exemplary structure including a first patterned material stack of sacrificial semiconductor material layers and semiconductor channel material layers located on a semiconductor substrate.

FIG. 2B is a cross sectional view of the first exemplary structure along cut Y1-Y1 shown in FIG. 1 that can be used in forming the low threshold voltage semiconductor device.

FIG. 3A is a cross sectional view of a second exemplary structure along cut X-X shown in FIG. 1 that can be used in forming a high threshold voltage semiconductor device, the second structure including a second patterned material stack of alternating sacrificial semiconductor material layers and semiconductor channel material layers located on the semiconductor substrate.

FIG. 3B is a cross sectional view of the second exemplary structure along cut Y2-Y2 shown in FIG. 1 that can be used in forming the high threshold voltage semiconductor device.

FIGS. 4A-4B are cross sectional views of the first exemplary structure of FIGS. 2A-2B, respectively, after forming a sacrificial gate structure and a gate spacer on a portion of the first patterned material stack, converting, by etching, the first patterned material stack into a first nanosheet stack of alternating sacrificial semiconductor material nanosheets and semiconductor channel material nanosheets, forming inner spacers, and forming source/drain regions.

FIGS. 5A-5B are cross sectional views of the second exemplary structure of FIGS. 3A-3B, respectively, after forming a sacrificial gate structure and a gate spacer on a portion of the second patterned material stack, converting, by etching, the second patterned material stack into a second nanosheet stack of alternating sacrificial semiconductor material nanosheets and semiconductor channel material nanosheets, forming inner spacers, and forming source/drain regions.

FIGS. 6A-6B are cross sectional views of the first exemplary structure of FIGS. 4A-4B, respectively, after forming an interlayer dielectric (ILD) layer.

FIGS. 7A-7B are cross sectional views of the second exemplary structure of FIGS. 5A-5B, respectively, after forming the ILD layer.

FIGS. 8A-8B are cross sectional views of the first exemplary structure of FIGS. 6A-6B, respectively, after revealing the first nanosheet stack and removing each sacrificial semiconductor material nanosheet of the first nanosheet stack.

FIGS. 9A-9B are cross sectional views of the second exemplary structure of FIGS. 7A-7B, respectively, after revealing the second nanosheet stack and removing each sacrificial semiconductor material nanosheet of the second nanosheet stack.

FIGS. 10A-10B are cross sectional views of the first exemplary structure of FIGS. 8A-8B, respectively, after forming a protective mask.

FIGS. 11A-11B are cross sectional views of the second exemplary structure of FIGS. 9A-9B, respectively, after trimming each semiconductor channel material nanosheet of the second nanosheet stack.

FIGS. 12A-12B are cross sectional views of the first exemplary structure of FIGS. 10A-10B, respectively, after removing the protective mask and forming a high-k gate dielectric layer.

FIGS. 13A-13B are cross sectional views of the second exemplary structure of FIGS. 11A-11B, respectively, after forming the high-k gate dielectric layer.

FIGS. 14A-14B are cross sectional views of the first exemplary structure of FIGS. 12A-12B, respectively, after forming a first diffusion barrier layer.

FIGS. 15A-15B are cross sectional views of the second exemplary structure of FIGS. 13A-13B, respectively, after forming a second diffusion barrier layer.

FIGS. 16A-16B are cross sectional views of the first exemplary structure of FIGS. 14A-14B, respectively, after forming a sacrificial dopant layer.

FIGS. 17A-17B are cross sectional views of the second exemplary structure of FIGS. 15A-15B, respectively, after forming the sacrificial dopant layer.

FIGS. 18A-18B are cross sectional views of the first exemplary structure of FIGS. 16A-16B, respectively, after performing a dopant diffusion anneal and removing at least the diffusion barrier layer.

FIGS. 19A-19B are cross sectional views of the second exemplary structure of FIGS. 17A-17B, respectively, after performing the dopant diffusion anneal and removing at least the diffusion barrier layer.

FIGS. 20A-20B are cross sectional views of the first exemplary structure of FIGS. 18A-18B, respectively, after forming a gate electrode.

FIGS. 21A-21B are cross sectional views of the second exemplary structure of FIGS. 19A-19B, respectively, after forming the gate electrode.

FIGS. 22A-22F are cross sectional view of various nanosheet transistors having low capacitance and varying threshold voltages of an exemplary semiconductor device in accordance with the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

To minimize capacitance in a semiconductor device containing a nanosheet transistor, it is desired to minimize the distance between the suspended portion of one semiconductor channel material nanosheet to the suspended portion of the nearest neighboring semiconductor channel material nanosheet in a nanosheet stack. The distance beneath the suspended portion of each semiconductor channel material nanosheet is oftentimes referred to as Tsus. Notably, Tsus denotes a thickness (or height) that is present beneath the suspended portion of each semiconductor channel material nanosheet. However, when Tsus is too small, some threshold voltage (Vt) adjustments cannot be achieved because there is not enough spacer between the suspended semiconductor channel material nanosheets to fit in a work function metal (WFM) or alternative high-k gate dielectric layer. The term “threshold voltage” is used throughout the present application to denote the voltage that must be applied to the gate structure of a transistor to turn the transistor “on” and allow a significant current to flow between the source region and the drain region. There is a need to provide a semiconductor device including nanosheet transistors having low capacitance and multiple threshold voltages.

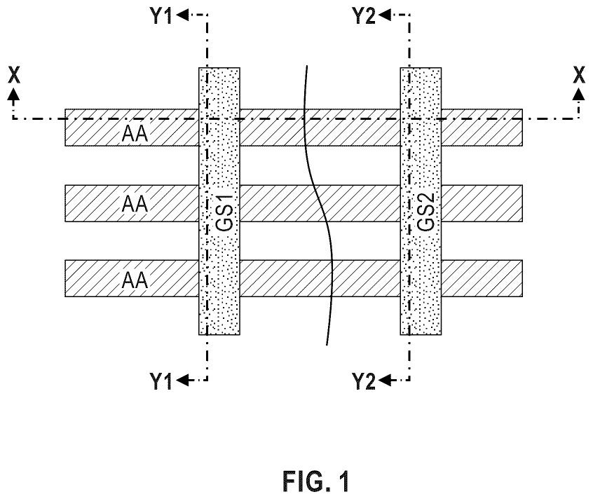

Referring first to FIG. 1, there is illustrated a device layout that can be used in accordance with an embodiment of the present application. The device layout includes at least one active area AA (three of which are shown by way of one example in FIG. 1) and two gate structures, namely GS1 and GS2. GS 1 is a gate structure for a low threshold voltage semiconductor, while GS2 is a gate structure for a high threshold voltage. The gate structures lie parallel to each other, and perpendicular to each of the active areas. In the present application, the low threshold voltage device has a lower threshold voltage than the high threshold voltage device. Typically, there is a 50 mV to 70 mV difference between a low threshold voltage device and a high threshold voltage device. Low threshold voltage semiconductor devices can be used in critical logic paths, while high threshold semiconductor devices can be used everywhere else including memory arrays for low stand by power.

FIG. 1 also includes cut X-X which is a cut through and along a length-wise direction of one of the active areas. FIG. 1 also includes cut Y1-Y1 which is a cut through and along a length-wise direction of GS1, and cut Y2-Y2 which is a cut through and along a length-wise direction of GS2. Note that in FIG. 1 a wavy line is present between GS1 and GS2 which denotes that a space can exist between the two gate structures.

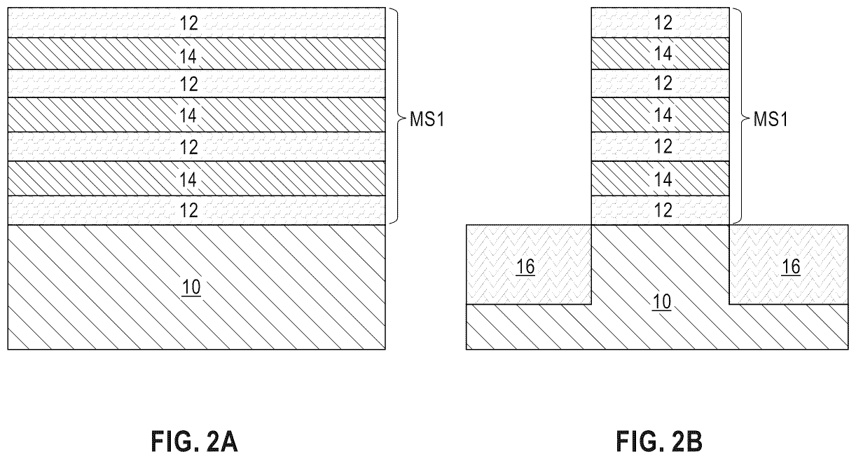

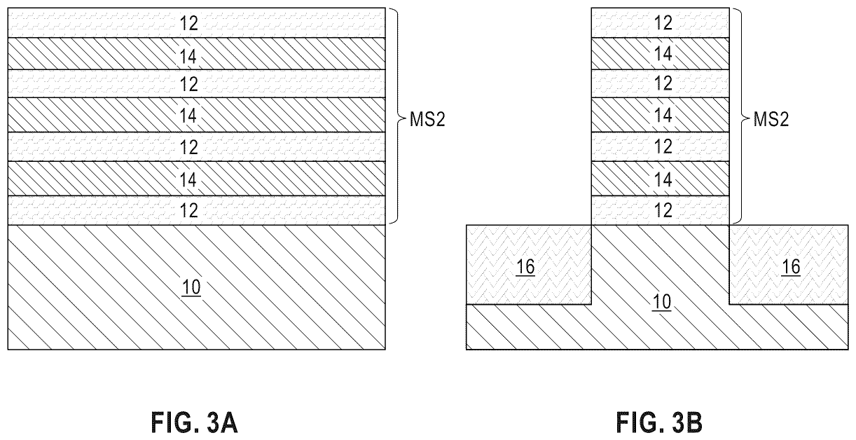

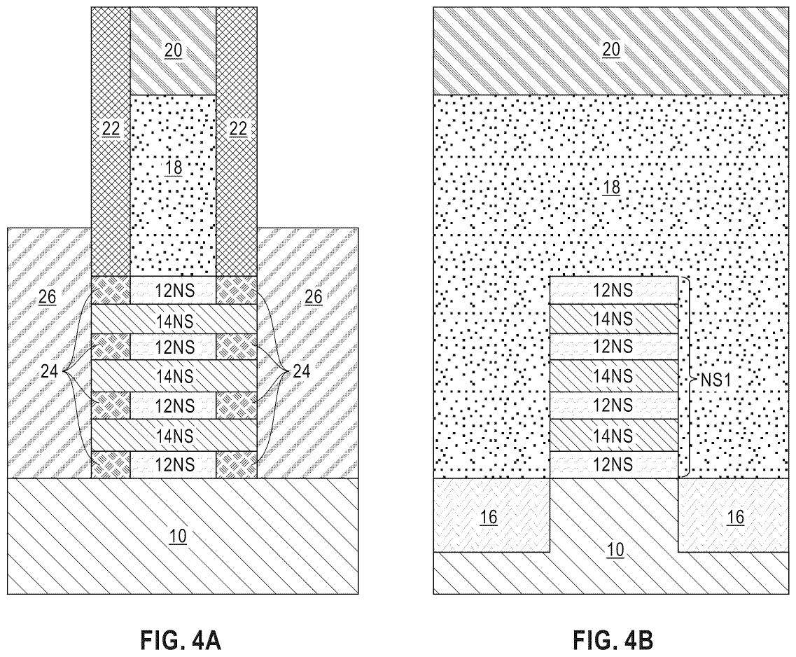

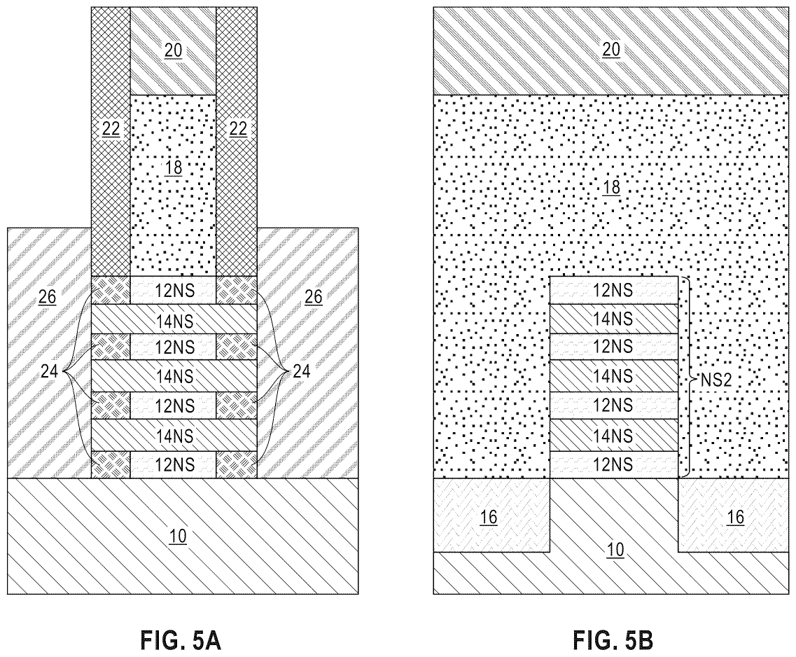

Reference is now made to FIGS. 2A-2B, which illustrate a first exemplary structure that can be used in forming a low threshold voltage semiconductor device of the present application, and FIGS. 3A-3B which illustrate a second exemplary structure that can be used in forming a high threshold voltage semiconductor device of the present application. It is noted that the second exemplary structure shown in FIGS. 3A-3B is located adjacent to the first exemplary structure shown in FIGS. 2A-2B and both the first exemplary structure and the second exemplary structure are formed on a same semiconductor substrate, i.e., semiconductor substrate 10 illustrated in FIGS. 2A-3B.

The first exemplary structure illustrated in FIGS. 2A-2B includes a first patterned material stack MS1 of alternating sacrificial semiconductor material layers 12 and semiconductor channel material layers 14 located on semiconductor substrate 10. The second exemplary structure illustrated in FIGS. 3A-3B includes second patterned material stack MS2 of alternating sacrificial semiconductor material layers 12 and semiconductor channel material layers 14 located on the semiconductor substrate 10. In FIG. 2B and FIG. 3B, a shallow trench isolation structure 16 is shown adjacent to a non-etched portion of semiconductor substrate 10 which is formed during the formation of the shallow trench isolation structure 16.

The semiconductor substrate 10 includes at least a semiconductor device layer. The semiconductor device layer is an uppermost portion of the semiconductor substrate 10 in which at least one semiconductor device such as, for example, a nanosheet transistor, will be formed thereon. The semiconductor substrate 10 can also include a semiconductor base layer and/or an etch stop layer. In one example, the semiconductor substrate 10 can include, from bottom to top, a semiconductor base layer, an etch stop layer and a semiconductor device layer. The semiconductor base layer of the semiconductor substrate 10 is composed of a first semiconductor material, and the semiconductor device layer of the semiconductor substrate 10 is composed of a second semiconductor material. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the semiconductor device layer can be compositionally the same as, or compositionally different from, the first semiconductor material that provides the semiconductor base layer. In some embodiments of the present application, the etch stop layer of the semiconductor substrate 10 can be composed of a dielectric material such as, for example, silicon dioxide and/or boron nitride. In other embodiments of the present application, the etch stop layer of the semiconductor substrate 10 is composed of a third semiconductor material that is compositionally different from the first semiconductor material that provides the semiconductor base layer and the second semiconductor material that provides the semiconductor device layer. In one example, the semiconductor base layer is composed of silicon, the etch stop layer is composed of silicon dioxide, and the semiconductor device layer is composed of silicon. In another example, the semiconductor base layer is composed of silicon, the etch stop layer is composed of silicon germanium, and the semiconductor device layer is composed of silicon.

Each sacrificial semiconductor material layer 12 present in MS1 and MS2 is composed of a fourth semiconductor material, while each semiconductor channel material layer 14 present in MS1 and MS2 is composed of a fifth semiconductor material that is compositionally different from the fourth semiconductor material. The fourth semiconductor material that provides each sacrificial semiconductor material layer 12 is compositionally different from the second semiconductor material that provides the semiconductor device layer of the semiconductor substrate 10. The fifth semiconductor material that provides each semiconductor channel material layer 14 can be compositionally the same as, or compositionally different from, the second semiconductor material that provides the semiconductor device layer of the semiconductor substrate 10. In some embodiments, the fifth semiconductor material that provides each semiconductor channel material layer 14 can be used to provide high channel mobility for NFET devices. In other embodiments, the fifth semiconductor material that provides each semiconductor channel material layer 14 can be used to provide high channel mobility for PFET devices. In some embodiments, the semiconductor device layer of the semiconductor substrate 10 and each semiconductor channel material layer 14 are composed of Si, while each sacrificial semiconductor material layer 12 is composed of a SiGe alloy.

It is noted that while the present application describes that the semiconductor channel material layers 14 present in MS1 and MS2 are composed of a same semiconductor material, embodiments are possible in which the semiconductor channel material layers 14 present in MS1 are compositionally different from the semiconductor channel material layers 14 present in MS2.

The number of sacrificial semiconductor material layers 12 and the number of semiconductor channel material layers 14 present in MS1 and MS2 may vary and are not limited to the embodiment illustrated in FIGS. 2A, 2B, 3A and 3B in which MS1 and MS2 include “n’ number of semiconductor channel material layers 14, and “n+1” number of sacrificial semiconductor material layers 12, wherein n is at least 2. In the illustrated embodiment, each semiconductor channel material layer 14 is located between a bottom sacrificial semiconductor material layer and a top sacrificial semiconductor material layer. In some embodiments, each of MS1 and MS2 can include “n” number of semiconductor channel material layers 14 and “n” number of sacrificial semiconductor material layers 12, wherein n is at least 2.

In the illustrated embodiment, MS1 and MS2 are of equal height. Embodiments are contemplated in which MS1 has a different height than MS2. While different heights are possible between MS1 and MS2 such embodiments provide a height variation between the two semiconductor device which can be problematic in some cases.

It is noted that while the present application describes and illustrates that MS1 and MS2 have an identical number of sacrificial semiconductor material layers 12 and an identical number of semiconductor channel material layers 14, embodiments are complemented in which MS1 has a different number of sacrificial semiconductor material layers 12 and a different number of semiconductor channel material layers 14 than MS2.

The shallow trench isolation structure 16 is located in an upper portion (i.e., the semiconductor device layer) of the semiconductor substrate 10. The shallow trench isolation structure 16 can include a trench dielectric liner and a trench dielectric material. The trench dielectric liner includes a trench dielectric liner material such as, for example, silicon nitride. The trench dielectric material is composed of any trench dielectric such as, for example, silicon dioxide. The trench dielectric liner is present along a sidewall and a bottom wall of the trench dielectric material. In some embodiments, the shallow trench isolation structure 16 can have a topmost surface that is substantially coplanar with a topmost surface of the semiconductor substrate 10. In other embodiments, the shallow trench isolation structure 16 can have a topmost surface that is vertically offset (i.e., higher or lower) than a topmost surface of the semiconductor substrate 10.

The first exemplary structure illustrated in FIGS. 2A-2B and the second exemplary structure illustrated in FIGS. 3A-3B can be formed by forming a non-patterned material stack of alternating sacrificial semiconductor material layers 12 and semiconductor channel material layers 14 on the semiconductor substrate 10. The forming of the non-patterned material stack can include one or more deposition processes including, for example, chemical vapor deposition (CVD), plasma enhanced chemical vapor deposition (PECVD), and/or epitaxial growth. Throughout the present application, the terms “epitaxial growth” or “epitaxially growing” mean the growth of a semiconductor material on a growth surface of another semiconductor material, in which the semiconductor material being grown has the same crystalline characteristics as the growth surface of the another semiconductor material. In an epitaxial deposition process, the chemical reactants provided by the source gases are controlled and the system parameters are set so that the depositing atoms arrive at the growth surface of the another semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 450° C. to 900° C. Although higher temperature typically results in faster deposition, the faster deposition may result in crystal defects and film cracking.

The non-patterned material stack is then patterned by lithographic patterning to provide MS1 and MS2. Lithographic patterning includes forming a photoresist material on a layer/multilayered stack that needs to be patterned, exposing the as deposited photoresist material to a desired pattern of irradiation, developing the photoresist material and transferring the pattern from the developed photoresist material into the layer/multilayered stack that needs to be patterned. The transferring of the pattern can include one or more etching processes. The one or more etching processes can include dry etching and/or wet etching. Dry etching can include reactive ion etching (RIE), plasma etching or ion beam etching. Wet etching can include the use of a chemical etchant that is selective in removing physically exposed portions of the layer/multilayered stack that needs to be patterned. The photoresist material is removed after the pattern transfer process utilizing a material removal process that is selective in removing the photoresist material.

After forming MS1 and MS2 by lithographic patterning, shallow trench isolation structure 16 is formed by forming a trench into the semiconductor substrate 10 and at a footprint of MS1 and MS2 and then filling the trench with the optional trench dielectric liner and the trench dielectric material. The filling includes deposition of an optional trench dielectric liner material, deposition of a trench dielectric material, planarization including, for example, chemical mechanical planarization (CMP), followed by an etch back process.

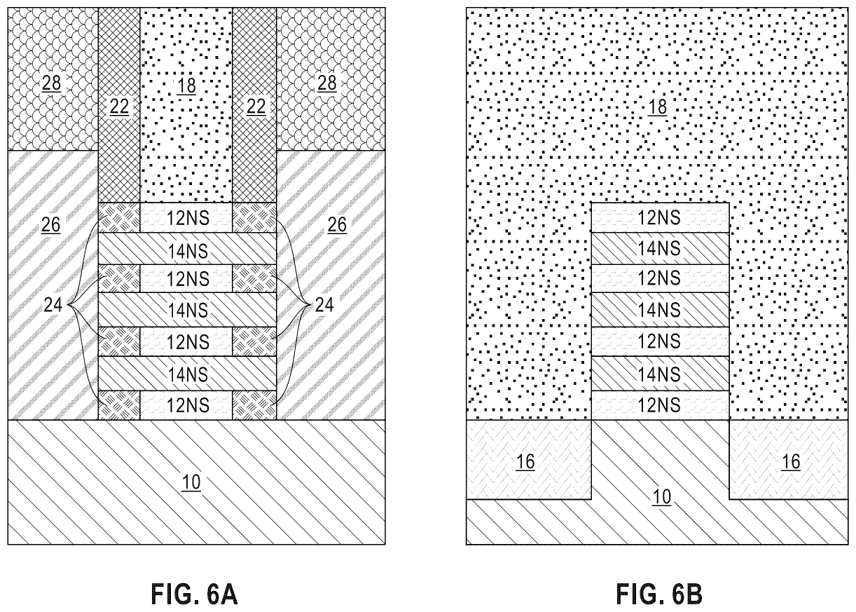

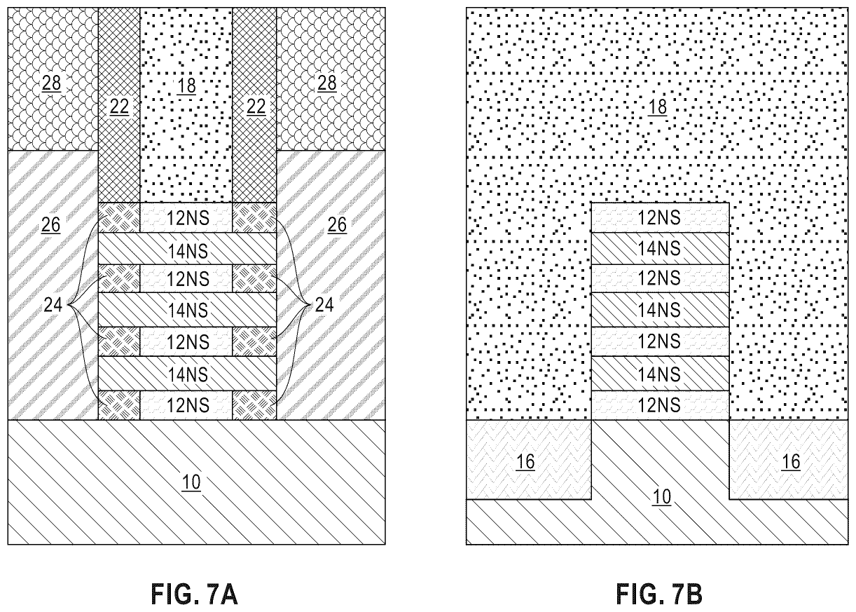

Next and as shown in FIGS. 4A-4B and FIGS. 5A-5B, a sacrificial gate structure 18 and a gate spacer 22 are formed on portion of both MS1 and MS2. In some embodiments, a sacrificial hard mask cap 20 can also be formed at this stage of the present application. Each sacrificial gate structure 18 includes at least a sacrificial gate material. In some embodiments, each sacrificial gate structure 18 can also include a sacrificial gate dielectric material. In such embodiments, the sacrificial gate dielectric material would be located beneath the sacrificial gate material. The optional sacrificial gate dielectric material can be composed of a dielectric material such as, for example, silicon dioxide. The sacrificial gate material can be composed of, for example, polysilicon, amorphous silicon, amorphous silicon germanium or amorphous germanium. When present, the sacrificial hard mask cap 20 is composed of any dielectric hard mask material such as, for example, silicon nitride, silicon oxide, and/or silicon oxynitride. The gate spacer 22 is composed of a dielectric spacer material including, but not limited to, silicon dioxide, SiN, SiBCN, SiOCN or SiOC.

The sacrificial gate structure 18 and, if present, the sacrificial hard mask cap 20 are formed by deposition of a blanket layer of at least the sacrificial gate material, followed by deposition of a blanket layer of the dielectric hard mask material. The blanket layer of at least the sacrificial gate material and the blanket layer of the dielectric hard mask material are then patterned to form the sacrificial gate structure 18 and the sacrificial hard mask cap 20, respectively on a portion of both of MS1 and MS2. Patterning can include a lithographic patterning process as defined above Gate spacer 22 is then formed by deposition of at least one of the dielectric spacer materials mentioned above, followed by a spacer etch.

After forming the gate spacer 22 and as further shown in FIGS. 4A-4B and 5A-5B, an etch such as, for example, RIE is used to convert, MS1 into a first nanosheet stack NS1 of alternating sacrificial semiconductor material nanosheets 12NS and semiconductor channel material nanosheets 14NS, and MS2 into a second nanosheet stacks NS2 of sacrificial semiconductor material nanosheets 12NS and semiconductor channel material nanosheets 14NS that are arranged/stacked in an alternating manner. Note that the etch used in the converting MS1 into NS1 and MS2 into NS2 utilizes the sacrificial gate structure 18 and the gate spacer 22 in the respective device areas as a combined etch mask. The sacrificial semiconductor material nanosheets 12NS in NS1 and NS2 are non-etched portions of the sacrificial semiconductor material layers 12 of MS1 and MS2, respectively, that are located beneath each combined etch mask, while the semiconductor channel material nanosheets 14NS in NS1 and NS2 are non-etched portions of semiconductor channel material layers 14 of MS1 and MS2, respectively, that are located beneath each combined etch mask. It is noted that each semiconductor channel material nanosheet 14NS present in NS1 and NS2 has a constant width from one end of the nanosheet to another end of the nanosheet.

After forming NS1 and NS2, and as further shown in FIGS. 4A-4B and 5A-5B, end portions of each sacrificial semiconductor material nanosheets 12NS in NS1 and NS2 are indented (via a recess etching process) to form a gap at the end of each sacrificial semiconductor material nanosheets 12NS in NS1 and NS2. An inner spacer 24 is then formed (via deposition and a recess etch) in each of the gaps.

After forming inner spacer 24, and as further shown in FIGS. 4A-4B and 5A-5B, source/drain regions 26 are formed by an epitaxial growth process. As used herein, a “source/drain” region can be a source region or a drain region depending on subsequent wiring and application of voltages during operation of the transistor. Each source/drain region 26 extends outward from a sidewall of each semiconductor channel material nanosheet 14NS present in NS1 and NS2. Each source/drain region 26 is composed of a sixth semiconductor material and a dopant. The sixth semiconductor material that provides each source/drain region 26 is composed of one of the semiconductor materials mentioned above. The sixth semiconductor material that provides the source/drain regions 26 can be compositionally the same as, or compositionally different from, the fifth semiconductor material that provides each semiconductor channel material nanosheet 14NS. The sixth semiconductor material that provides each source/drain region 26 is however compositionally different from the fourth semiconductor material that provides each sacrificial semiconductor material nanosheet 12NS. The dopant that is present in the source/drain regions 26 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each of the source/drain regions 26 can have a dopant concentration of from 4×10²⁰ atoms/cm³ to 3×10²¹ atoms/cm³. Although the present application describes and illustrates that the source/drain regions 26 of the first exemplary structure are of a same conductivity type as the source/drain regions 26 of the second exemplary structure, embodiments are contemplated in which the source/drain regions 26 of the first exemplary structure are of a different conductivity type than the source/drain regions 26 of the second exemplary structure.

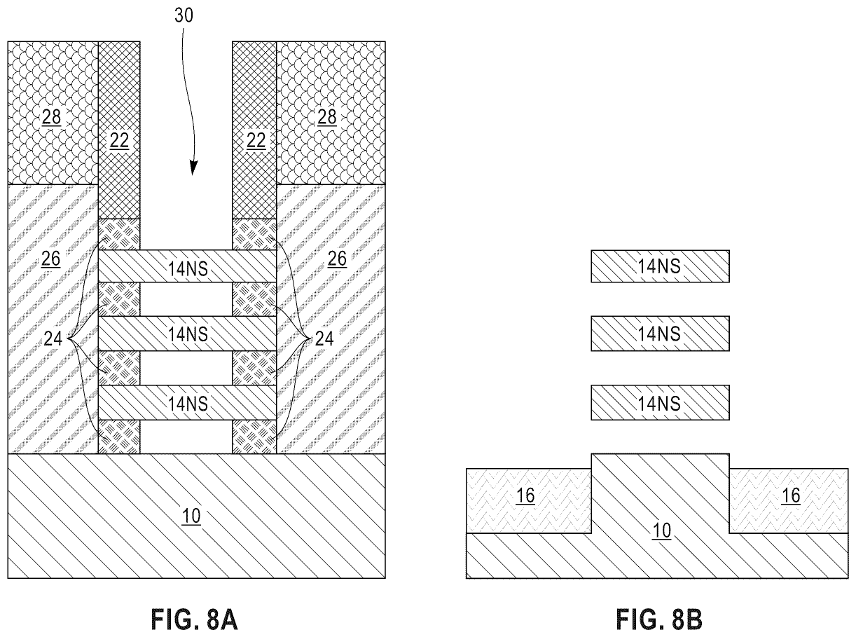

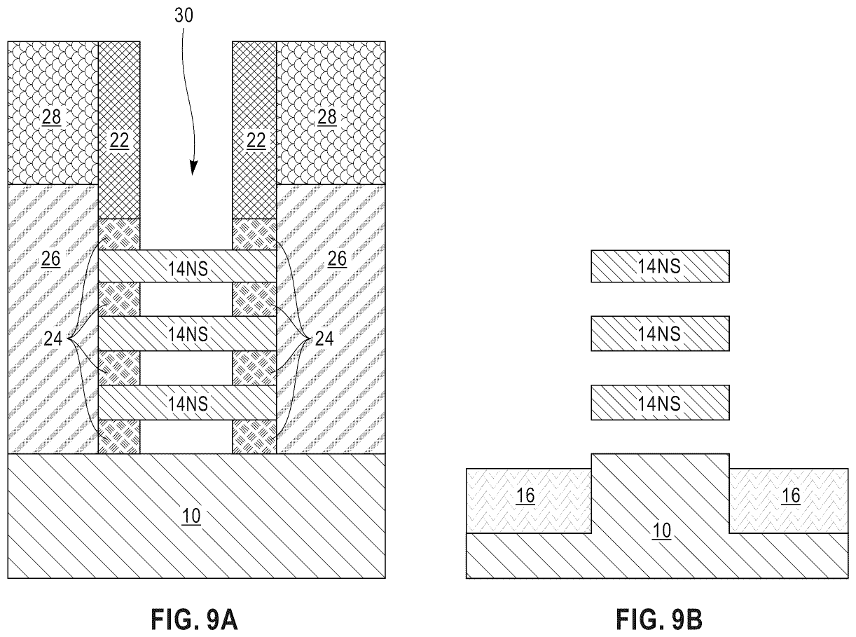

Next and as is shown in FIGS. 6A-6B and FIGS. 7A-7B, an ILD layer 28 is formed. The ILD layer 28 is formed on top of, and adjacent to, each source/drain region 26. The ILD layer 28 is composed of a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0 (all dielectric constants mentioned herein are measured in a vacuum unless otherwise noted). The ILD layer 28 can be formed by a deposition process including, but not limited to, CVD, PECVD or spin-on coating. A planarization process such as, for example, CMP follows the deposition process. The planarization process removes an upper portion of the gate spacer 22 and, if present, the sacrificial hard mask cap 20 revealing the sacrificial gate structure 18 of both the first exemplary structure and the second exemplary structure as is illustrated in FIGS. 6A-6B and FIGS. 7A-7B.

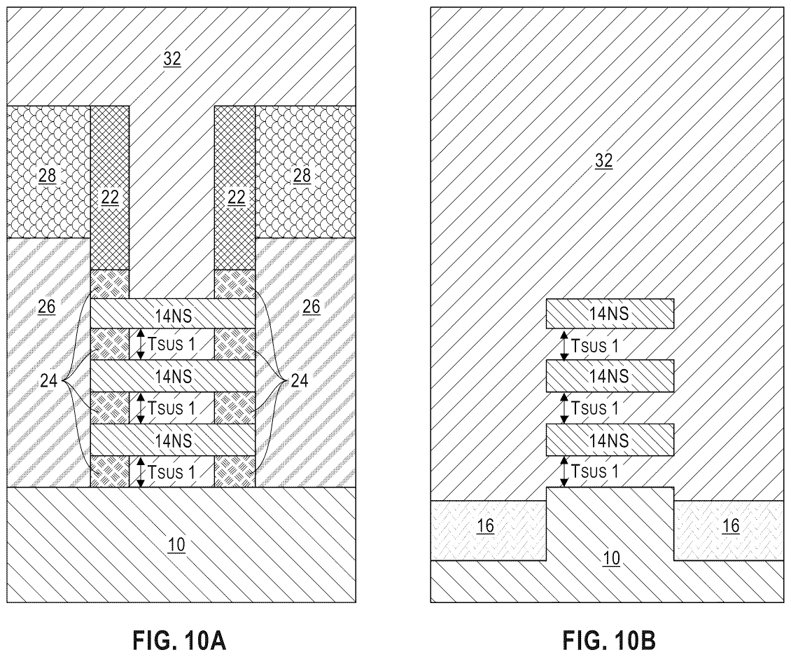

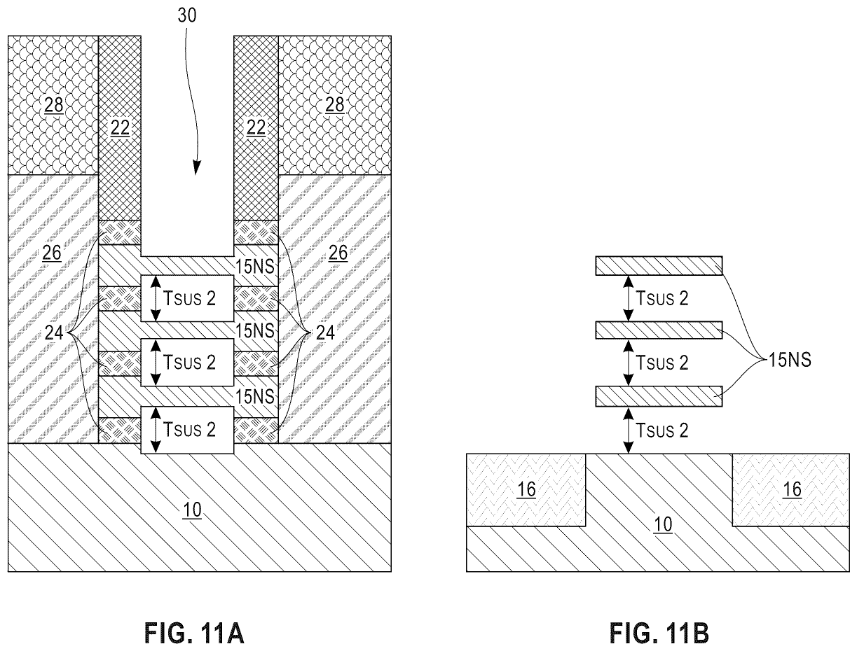

Next, and as shown in FIGS. 8A-8B and FIGS. 9A-9B, NS1 of the first exemplary structure and NS2 of the second exemplary structure are revealed, and thereafter each sacrificial semiconductor material nanosheet 12NS of NS1, and each sacrificial semiconductor material nanosheet 12NS of NS2 are removed. The sacrificial gate structures 18 can be removed utilizing any material removal process such as, for example, etching, which is selective in removing the sacrificial gate structures 18. The removal of the sacrificial gate structures 18 reveals NS1 and NS2. Next, the sacrificial semiconductor material nanosheets 12NS of NS1 and NS2 are removed so as to suspend a middle portion (i.e., channel portion) of each semiconductor channel material nanosheet 14NS in NS1 and NS2. The removal of the sacrificial semiconductor material nanosheets 12NS includes any material removal process such as, for example, etching, which is selective in removing the sacrificial semiconductor material nanosheets 12NS. It is noted that the semiconductor channel material nanosheets 14NS in NS1 and NS2 are not floating as appears to be the case in the cross sectional views shown in FIGS. 8B and 9B, but rather they are anchored in place as is shown in FIGS. 8A and 9A. The removal of the sacrificial semiconductor material nanosheets 12NS in NS1 and NS2 creates gate cavity 30 in the area including the first exemplary structure (se, for example, FIGS. 8A-8B), and in the area including the second exemplary structure (see, for example, FIGS. 9A-9B).

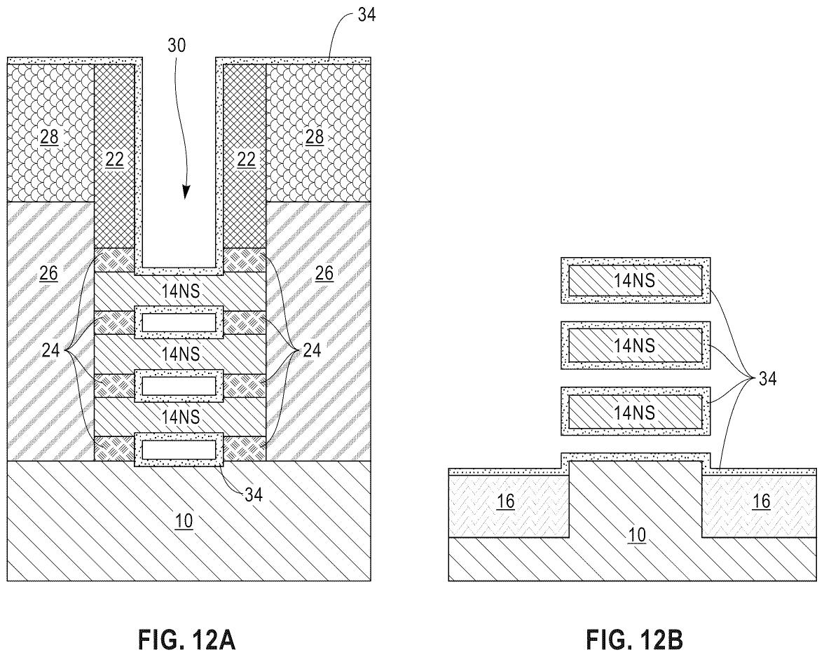

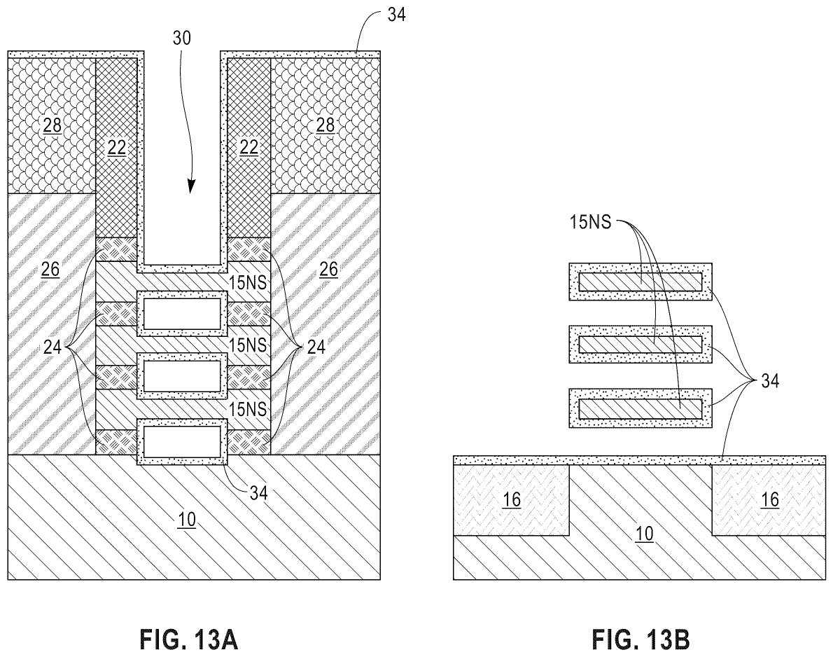

After removing each of the sacrificial semiconductor material nanosheets 12NS in NS1 and NS2, a protective mask 32 is formed in the area including the first exemplary structure (see, for example, FIGS. 10A-10B), but not the area including the second exemplary structure (see, for example, FIGS. 11A-11B). Protective mask 32 is formed in the gate cavity 30 of the first exemplary structure and on top the ILD layer 28 and gate spacer 22 of the first exemplary structure. The protective mask 32 includes any well known masking material or masking material stack. In one example, the protective mask 32 is composed of an organic planarization material. The protective mask 32 can be formed by deposition of at least one masking material, followed by lithographic patterning. The lithographic patterning removes as-deposited masking material from the area including the second exemplary structure (see, for example, FIGS. 11A-11B), while maintaining masking material in the area including the first exemplary structure (See, for example FIGS. 10A-10B). The maintained masking material forms the protective mask 32.

With the protective mask 32 in place, the middle portion of each semiconductor channel material nanosheet 14NS in NS2 can be trimmed to provide dog-bone shaped nanosheets 15NS. Each dog-bone shaped nanosheets has end portions that have a thickness that is greater than a thickness of the middle portion (i.e., channel portion) of each dog-bone shaped nanosheet 15NS. Each dog-bone shaped nanosheet 15NS can also be referred to as a dumb-belled shaped nanosheet. Trimming of each semiconductor channel material nanosheet 14NS in NS2 can be performed utilizing any nanosheet trimming process well known to those skilled in the art. In one example, trimming of each semiconductor channel material nanosheet 14NS in NS2 can be performed by oxidizing the physically exposed middle portion of each semiconductor channel material nanosheet 14NS of NS2, followed by etching (the oxidizing and etching steps can be repeated numerous times to provide a desired thickness to the middle portion of each dog-bone shaped nanosheet 15NS of NS2). In another example, trimming can be performed by diffusion Ge into the physically exposed middle portion of each semiconductor channel material nanosheet 14NS of NS2, followed by an etch. In some embodiments, an upper portion of the semiconductor substrate 10 can also be removed as is shown in FIG. 11A. during the trimming process.

As a result of trimming each semiconductor channel material nanosheet 14NS in NS2, the thickness of the area located beneath each dog-bone shaped nanosheet 15NS of NS2 (hereinafter “Tsus2”) is greater than the thickness of the area beneath each semiconductor channel material nanosheets 14NS of NS1 (hereinafter “Tsus1”). In some embodiments, Tsus1 is less than, or equal to 7 nm. Such a small Tsus provides parasitic reduction which in turn can affect the device performance of such a transistor. Tsus2 is greater than 7 nm. In some embodiments, Tsus2 is from 8 nm to 12 nm. A larger Tsus allows more space for diffusion barrier deposition and thus enables tunning dopant diffusion into high-k gate dielectrics (further tunning the threshold voltage of the device). The dog-bone shaped nanosheets 15NS provide more volume for a gate structure to be formed beneath each of the dog-bone shaped nanosheets 15NS as compared to the semiconductor channel material nanosheets 14NS of NS1.

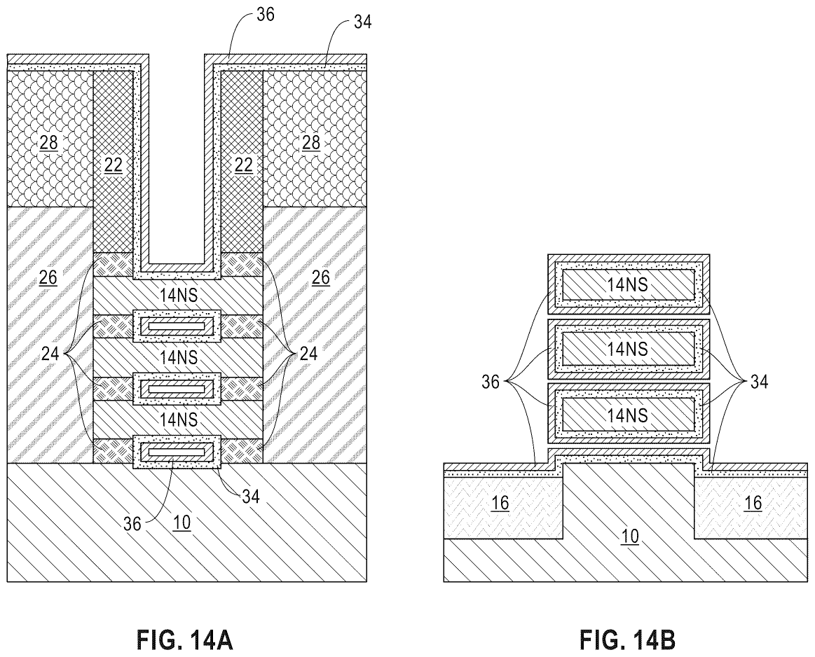

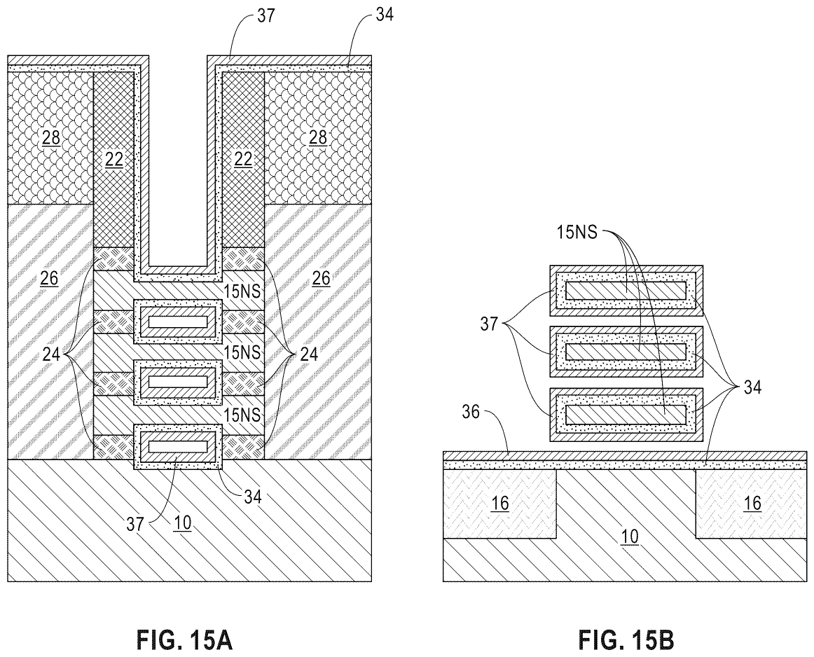

Next, and as illustrated in FIGS. 12A-12B, the protective mask 32 is removed from the first exemplary structure. The removal of the protective mask 32 can be performed utilizing any material removal process that is selective in removing the at least one masking material that provides the protective mask 32. In one example, and when the protective mask 32 is composed of an organic planarization material, the protective mask 32 can be removed by ashing. After removing the protective mask 32, a high-k gate dielectric layer 34 is formed in the area including the first exemplary structure (see, for example, FIGS. 12A-12B) and the area including the second exemplary structure (see, for example, FIGS. 13A-13B). In the area including the first exemplary structure, the high-k gate dielectric layer 34 is disposed on physically exposed surfaces (top and bottom) of each semiconductor channel material nanosheet 14NS of NS1, on a physically exposed surface of semiconductor substrate 10, and on a physically exposed surface of the shallow trench isolation structure 16. The high-k gate dielectric layer 34 that is formed in the area including the first exemplary structure is also disposed along the physically exposed sidewalls of each inner spacer 24 and gate spacer 22 as well as on top the ILD layer 28. In the area including the second exemplary structure, the high-k gate dielectric layer 34 is disposed on physically exposed surfaces (top and bottom) of each dog-bone shaped nanosheet 15NS of NS2, on a physically exposed surface of semiconductor substrate 10, and on a physically exposed surface of the shallow trench isolation structure 16. The high-k gate dielectric layer 34 that is formed in the area including the second exemplary structure is also disposed along the physically exposed sidewalls of each inner spacer 24 and gate spacer 22 as well as on top the ILD layer 28.

The high-k gate dielectric layer 34 is composed of a gate dielectric material having a dielectric constant of greater than 4.0 (i.e., a high-k gate dielectric). Illustrative examples of gate dielectric materials (i.e., high-k gate dielectrics) include, but are not limited to, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The high-k gate dielectric layer 34 can be formed by a deposition process such as, for example, CVD, PECVD or atomic layer deposition (ALD).

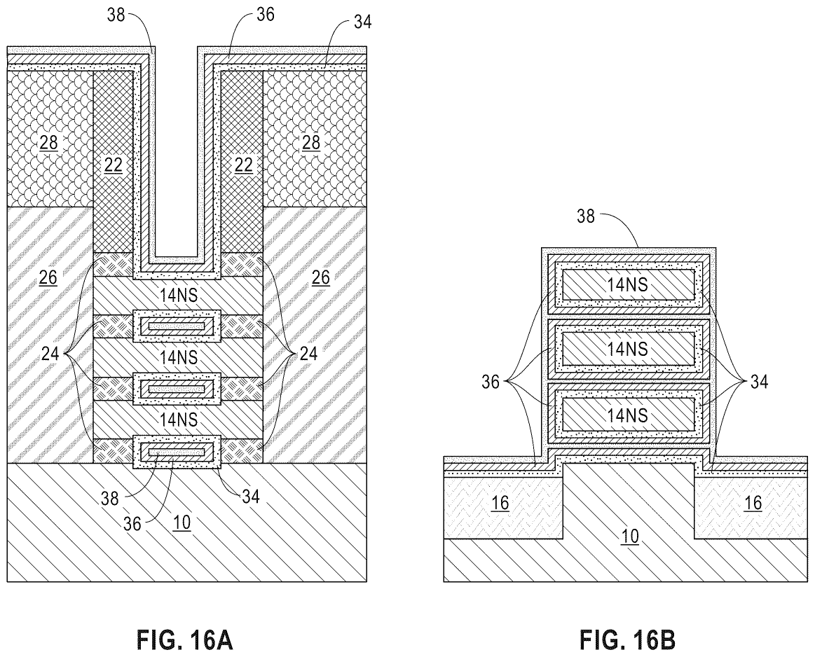

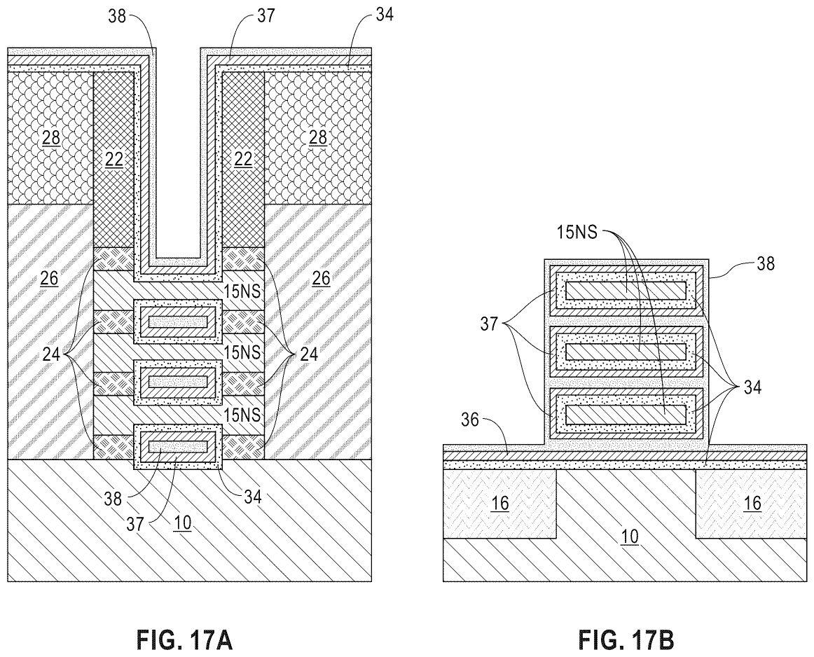

Next, and as is illustrated in FIGS. 14A-14B, a first diffusion barrier layer 36 is formed on the high-k gate dielectric layer 34 that is present in the area including the first exemplary structure, and as is illustrated in FIGS. 15A-15B, a second diffusion barrier layer 37 is formed on the high-k gate dielectric layer. 34 that is present in the area including the second exemplary structure. The first diffusion barrier layer 36 and the second diffusion barrier layer 37 are composed of any diffusion barrier material such as, for example, Ta, TaN, Ti, TiN or any multilayered combination of such diffusion barrier materials. The first diffusion barrier layer 36 and the second diffusion barrier layer 37 can be compositionally the same, or they can be compositionally different from each other. In one example, the first diffusion barrier layer 36 and the second diffusion barrier layer 37 are both composed of TiN. The first diffusion barrier layer 36 and the second diffusion barrier layer 37 can be formed by depositing (e.g., CVD, PECVD, ALD or physical vapor deposition (PVD)) a first diffusion barrier material on the high-k gate dielectric layer 34 that is present in the area including the first exemplary structure, and in the area including the second exemplary structure. The as-deposited first diffusion barrier material in the area including the first exemplary structure is the first diffusion barrier layer 36. A block mask (not shown) is then formed on the as-deposited first diffusion barrier material in the area including the first exemplary structure, and thereafter a second diffusion barrier material (compositionally the same or compositionally different from the first diffusion barrier material) is deposited (e.g., CVD, PECVD. ALD or PVD) on the as-deposited first diffusion barrier material in the area including the second exemplary structure. Collectively, the as-deposited first diffusion barrier material and the as-deposited second diffusion barrier material that are present in the area including the second exemplary structure provide the second diffusion barrier layer 37. The block mask is removed after depositing the second diffusion barrier material. In the present application, the first diffusion barrier layer 36 has a first thickness, and the second diffusion barrier layer 37 has a second thickness in which the second thickness is greater than the first thickness. In one example, the first thickness of the first diffusion barrier layer 36 is 1 nm, and the second thickness of the second diffusion barrier layer 37 is from 2 nm to 2.5 nm. In some embodiments and in the area including the second exemplary structure (in which a high threshold voltage device will be formed), the second thickness of the second diffusion barrier layer 37 allows less dopant diffusion into the high-k gate dielectric layer 34 that is present in that area as compared to the area including the first exemplary structure.

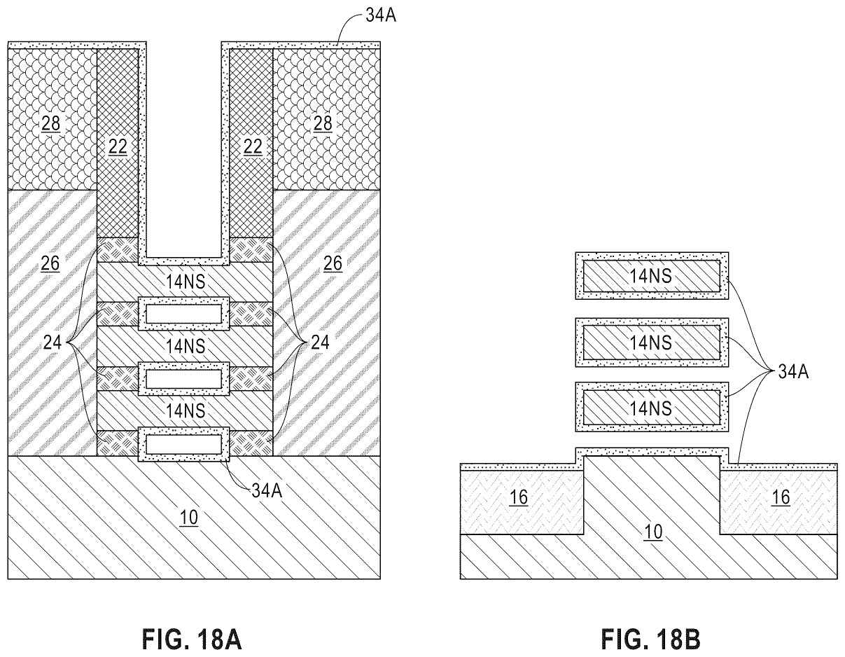

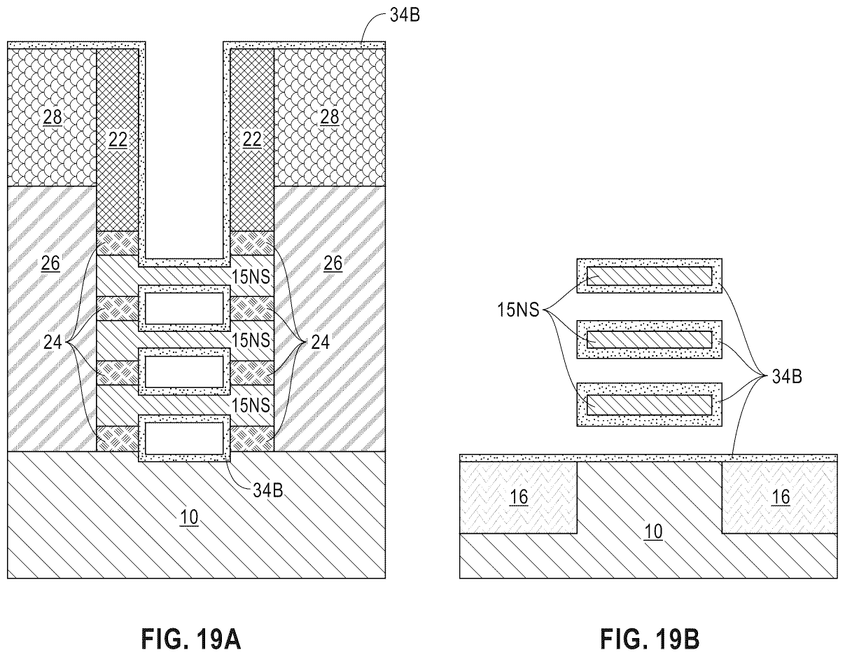

After forming the first diffusion barrier layer 36 and the second diffusion barrier layer 37, a sacrificial dopant layer 38 is formed on the first diffusion barrier layer 36 (see, for example, FIGS. 16A-16B) and the second diffusion barrier layer 37 (see, for example, FIGS. 17A-17B). In some embodiments, and when NFETs are to be formed, the sacrificial dopant layer 38 is composed of a Group 2 metal oxide (e.g., MgO) or a Group 3 metal oxide (e.g., LaO). In some embodiments, and when PFETs are to be formed, the sacrificial dopant layer 38 is composed of a Group 4 metal oxide (e.g., TiO) or a Group 13 metal oxide (e.g., AlO). The Group 2, Group 3, Group 4 and Group 13 metal oxides include a dopant metal (e.g., Mg, La, Ti or Al) that will be subsequently introduced via a dopant diffusion anneal into the high-k gate dielectric layer 34. Note that Tsus1 is sufficient enough to permit the sacrificial dopant layer 38 to be formed in the area beneath each semiconductor channel material nanosheet 14NS of NS1, and Tsus2 is sufficient enough to permit the sacrificial dopant layer 38 to be formed in the area beneath each dog-bone shaped nanosheet 15NS of NS2 despite the presence of a thicker diffusion barrier layer (i.e., the second diffusion barrier layer 37). The sacrificial dopant layer 38 can be formed utilizing a deposition process including, but not limited to, CVD, PECVD, ALD, PVD or sputtering.

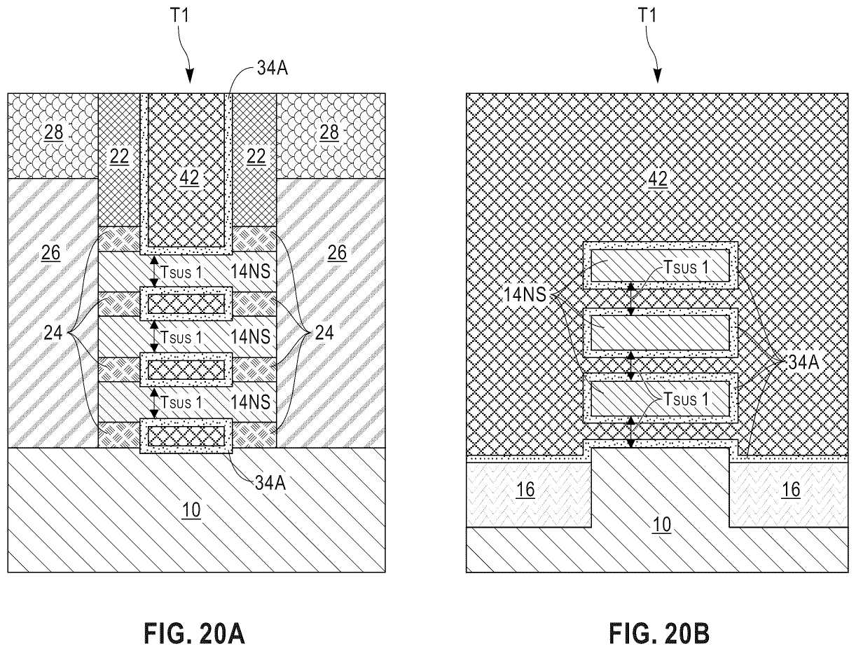

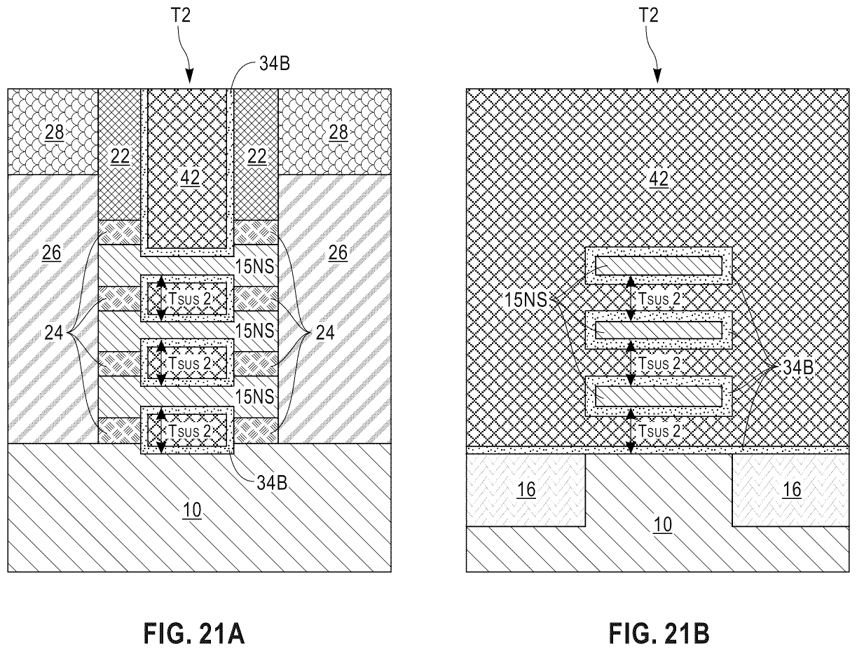

After forming the sacrificial dopant layer 38, a dopant diffusion anneal is used to drive the dopant metal from the sacrificial dopant layer 38 into the high-k gate dielectric layer 34 to provide a first metal doped high-k gate dielectric layer 34A in the area including the first exemplary structure (see, for example, FIGS. 18A-18B), and a second metal doped high-k gate dielectric layer 34B in the area including the second exemplary structure (see, for example, FIGS. 19A-19B).

Prior to performing the dopant diffusion anneal, an amorphous silicon layer (not shown) can be formed on the sacrificial dopant layer 38 by a deposition process such as, for example, CVD, PECVD or PVD. The amorphous silicon layer serves as a protective layer for a subsequently performed dopant diffusion anneal. In some embodiments, formation of the amorphous silicon layer can be omitted. The dopant diffusion anneal is performed at a temperature that is sufficient to cause diffusion of the dopant metal from the sacrificial dopant layer 38 into the high-k gate dielectric layer 34 that is present in both the area including the first exemplary structure, and the area including the second exemplary structure. Typically, the dopant diffusion anneal is performed at a temperature from 600° C. to 1200° C., with a temperature from 850° C. to 1000° C. being more typical. The duration of the dopant diffusion anneal may vary depending on the type of metal dopant and temperature of the dopant diffusion anneal. In one example, the duration of the dopant diffusion anneal is from 1 milli-second to 1 second. The dopant diffusion anneal is performed in an inert ambient such as, for example, He, Ar, Ne or any mixture thereof. After the dopant diffusion anneal, the sacrificial dopant layer 38 is deficient of dopant metal. After the dopant diffusion anneal and as illustrated in FIGS. 18A-18B and FIGS. 19A-19B, the optional amorphous silicon layer, the remaining sacrificial dopant layer 38 the first diffusion barrier layer 36, and the second diffusion barrier layer 37 are removed utilizing one or more material removal process that are selective in removing each of the optional amorphous silicon layer, the remaining sacrificial dopant layer 38 the first diffusion barrier layer 36, and the second diffusion barrier layer 37.

The first metal doped high-k gate dielectric layer 34A has a first metal dopant concentration, while the second metal doped high-k gate dielectric layer 34B has a second metal dopant concentration. In some embodiments, the second dopant concentration is less than the first metal dopant concentration. The difference in metal dopant concentration that is present in the first metal doped high-k gate dielectric layer 34A and the second metal doped high-k gate dielectric layer 34B is a direct result of the thickness of diffusion barrier layer that was present in that area of the structure. Namely, the first diffusion barrier layer 36 which is thin (as compared to the second diffusion barrier layer 37) allows more metal dopant diffusion into the high-k gate dielectric layer 34 than the thicker second diffusion barrier layer 37. In some embodiments (depending on the thickness of the first and second diffusion barrier layers and the anneal conditions), the second metal dopant concentration can equal the first metal dopant concentration.

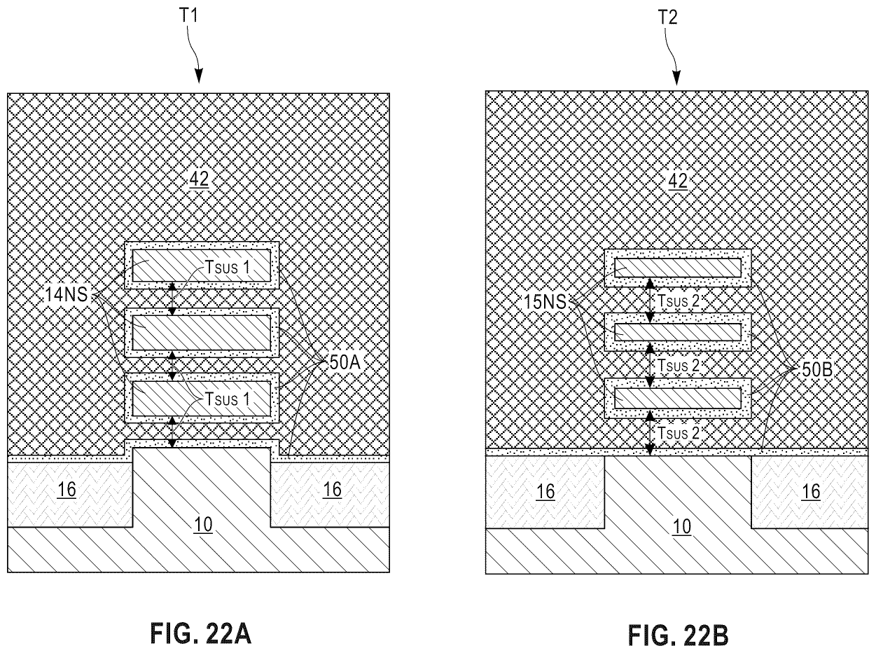

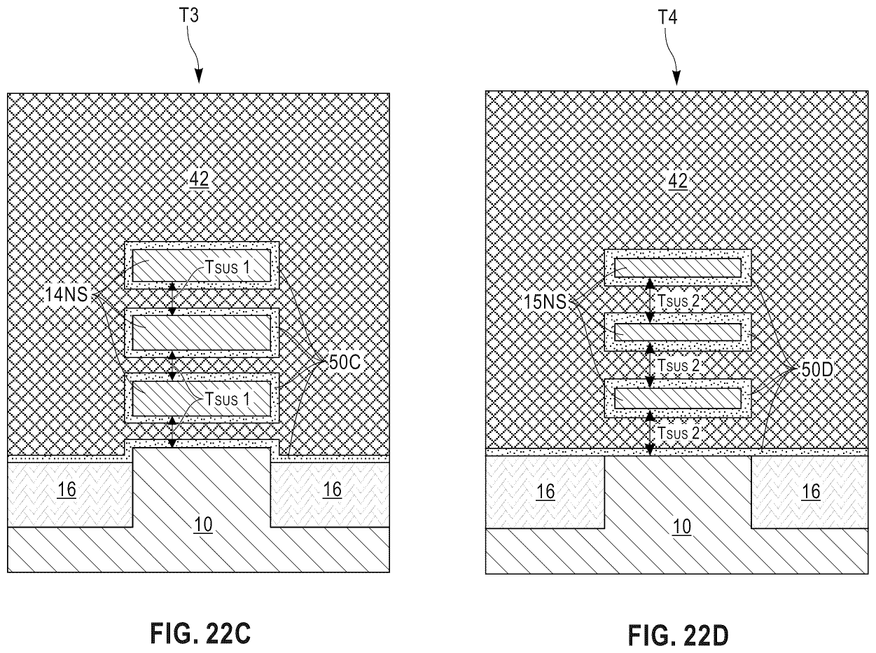

A gate electrode 42 is then formed in both the area including the first exemplary structure (see, for example, FIGS. 20A-20B) and the area including the second exemplary structure (see, for example, FIGS. 21A-21B). In the area including the first exemplary structure (see, for example, FIGS. 20A-20B), the gate electrode 42 is formed on the first metal doped high-k gate dielectric layer 34A. Collectively, the first metal doped high-k gate dielectric layer 34A and the gate electrode 42 provide a first gate structure that wraps around a middle portion of each of the semiconductor channel material nanosheets 14NS of NS1. In the area including the second exemplary structure (see, for example, FIGS. 21A-21B), the gate electrode 42 is formed on the second metal doped high-k gate dielectric layer 34B. Collectively, the second metal doped high-k gate dielectric layer 34B and the gate electrode 42 provide a second gate structure that wraps around a middle portion of each dog-bone shaped nanosheet 15NS of NS2. In accordance with the present application, the first gate structure has a first threshold voltage and the second gate structure has a second threshold voltage in which the second threshold voltage is greater than the first threshold voltage. The different threshold voltage is a result of the difference in Tsus between the two structures, and also (if applicable) the different dopant concentration of the metal doped high-k gate dielectric layers.

The gate electrode 42 can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co). The gate electrode 42 can be formed by deposition, followed by planarization. The planarization process removes the gate electrode material, the first metal doped high-k gate dielectric layer 34A, and the second metal doped high-k gate dielectric layer 34B that is formed on top of the ILD layer 28 and the gate spacer 22.

Notably, FIGS. 20A-21B illustrates a semiconductor device in accordance with an embodiment of the present application. The illustrated semiconductor device includes first nanosheet transistor T1 including a first nanosheet stack NS1 of semiconductor channel material nanosheets 14NS having a first thickness (i.e., Tsus1) located beneath a suspended portion of each semiconductor channel material nanosheet, and a first gate structure including first metal doped high-k gate dielectric layer 34A having a first metal dopant concentration wrapped around the suspended portion of each semiconductor channel material nanosheet 14NS. The semiconductor device further includes a second nanosheet transistor T2 located adjacent to the first nanosheet transistor T1. The second nanosheet transistor T2 includes a second nanosheet stack NS2 of dog-bone shaped nanosheets 15NS having a second thickness (i.e., Tsus2) located beneath a suspended portion of each of the dog-bone shaped nanosheets 15NS, and a second gate structure including second metal doped high-k gate dielectric layer 34B having a second metal dopant concentration wrapped around the suspended portion of each of the dog-bone shaped nanosheets 15NS. In accordance with the present application, the second thickness is greater than the first thickness. By controlling the first thickness (Tsus1) and second thickness (Tsus2), a low capacitance nanosheet containing device is provided in which the nanosheet transistors have multiple threshold voltages.

In the illustrated embodiment of FIGS. 20A-21B, T1 and T2 have low capacitance and different threshold voltages. Notably, and for the illustrated embodiment illustrated in FIGS. 20A-21B, T1 has a first threshold voltage (Vt1), while T2 has a second threshold voltage (Vt2) in which Vt2 is greater than Vt1.

In some embodiments and for the embodiment illustrated in FIGS. 20A-21B, the second dopant concentration is less than the first metal dopant concentration. The different dopant concentration in the first metal doped high-k gate dielectric layer 34A and in the second metal doped high-k gate dielectric layer 34B can add a further differential in the threshold voltages between T1 and T2 in FIGS. 20A-21B.

In some embodiments and for the embodiment illustrated in FIGS. 20A-21B, the second dopant concentration is equal to the first metal dopant concentration.

In some embodiments and for the embodiment illustrated in FIGS. 20A-21B, the first metal doped high-k gate dielectric layer 34A and the second metal doped high-k gate dielectric layer 34B include a Group 2 metal (e.g., Mg). Group 2 metals are used in providing NFETs.

In some embodiments and for the embodiment illustrated in FIGS. 20A-21B, the first metal doped high-k gate dielectric layer 34A and the second metal doped high-k gate dielectric layer 34B include a Group 3 metal (e.g., La). Group 3 metals are used in providing NFETs.

In some embodiments and for the embodiment illustrated in FIGS. 20A-21B, the first metal doped high-k gate dielectric layer 34A and the second metal doped high-k gate dielectric layer 34B include a Group 4 metal (e.g., Ti). Group 4 metals are used in providing PFETs.

In some embodiments and for the embodiment illustrated in FIGS. 20A-21B, the first metal doped high-k gate dielectric layer 34A and the second metal doped high-k gate dielectric layer 34B include a Group 13 metal (e.g., Al). Group 13 metals are used in providing PFETs.

In embodiments and for the embodiment illustrated in FIGS. 20A-21B, the first gate structure and the second gate structure further include a gate electrode 42 in which the gate electrode 42 includes at least a work function metal. Work function metals are used to set threshold voltage of the nanosheet transistor.

In embodiments and for the embodiment illustrated in FIGS. 20A-21B, the semiconductor device further includes semiconductor substrate 10 located beneath the first nanosheet transistor T1 and the second nanosheet transistor T2. In such embodiments, the first metal doped high-k gate dielectric layer 34A and the second metal doped high-k gate dielectric layer 34B are present on the semiconductor substrate 10.

In embodiments and for the embodiment illustrated in FIGS. 20A-21B, the semiconductor device further includes shallow trench isolation structure 16 located in an upper portion of the semiconductor substrate 10. In such embodiments, the first metal doped high-k gate dielectric layer 34A and the second metal doped high-k gate dielectric layer 34B are present on the shallow trench isolation structure 16.

In some embodiments and for the embodiment illustrated in FIGS. 20A-21B, the first thickness (i.e., Tsus1) is equal to or less than 7 nm. With such a small Tsus, parasitic capacitance can be reduced and therefore benefit device performance of such a transistor.

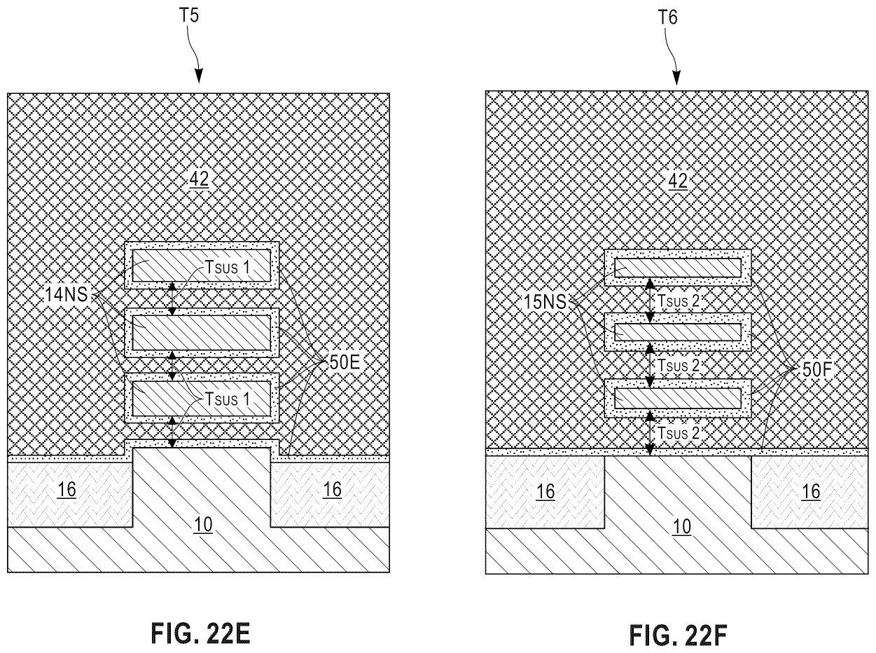

FIGS. 22A-22F illustrate various nanosheet transistors, namely first nanosheet transistor T1, second nanosheet transistor T2, third nanosheet transistor T3, fourth nanosheet transistor T4, fifth nanosheet transistor T5, and sixth nanosheet transistor T6, having low capacitance and varying threshold voltages of an exemplary semiconductor device in accordance with the present application; the cross sectional views are across each nanosheet stack and are thus similar to the Y1-Y1 and Y2-Y2 cuts shown in FIG. 1. Each of the nanosheet transistors, namely T1-T6, shown in FIGS. 22A-22F is located on a same substrate, i.e. semiconductor substrate 10. Shallow trench isolation structure 16 can be located adjacent to a non-etched portion of the semiconductor substrate 10. Note that T1 and T2 of this embodiment, are different from T1 and T2 mentioned in the previous embodiment as illustrated in FIGS. 20A-21B

The nanosheet transistors (e.g., T1, T3 and T5) illustrated in FIGS. 22A, 22C and 22E include a nanosheet stack of semiconductor channel material nanosheets 14NS having Tsus1, and a high-k gate dielectric layer and a gate electrode 42 wrapped around the semiconductor channel material nanosheets 14NS. Notably, the high-k gate dielectric layer of the first nanosheet transistor T1 is a first high-k gate dielectric layer 50A having a first metal dopant concentration C1, the high-k gate dielectric layer of the third nanosheet transistor T3 is a third high-k gate dielectric layer 50C having a third metal dopant concentration C3, and the high-k gate dielectric layer of the fifth nanosheet transistor T5 is a fifth high-k gate dielectric layer 50E that is devoid of metal dopants. In the illustrated embodiment, C1 is greater than C3.

The nanosheet transistors (e.g., T2, T4 and T6) illustrated in FIGS. 22B, 22D and 22F include a nanosheet stack of dog-bone shaped nanosheets 15NS having Tsus2, and a high-k gate dielectric layer and a gate electrode 42 wrapped around the dog-bone shaped nanosheets 15NS. Notably, the high-k gate dielectric layer of the second nanosheet transistor T2 is a second high-k gate dielectric layer 50B having a second metal dopant concentration C2, the high-k gate dielectric layer of the fourth nanosheet transistor T4 is a fourth high-k gate dielectric layer 50D having a fourth metal dopant concentration C4, and the high-k gate dielectric layer of the sixth nanosheet transistor T6 is a sixth high-k gate dielectric layer 50F that is devoid of metal dopants. In In the illustrated embodiment, C2 is greater than C4. In the illustrated embodiment, C1=C2, C3=C4, and C1 and C2 are greater than C3 and C4.

In the illustrated embodiment illustrated in FIGS. 22A-22F, T1 has a first threshold voltage (Vt1), T2 has a second threshold voltage (Vt2), T3 has a third threshold voltage (Vt3), T4 has a fourth threshold voltage (Vt4), T5 has a fifth threshold voltage (Vt5), and T6 has a first threshold voltage (Vt6) in which Vt1<Vt2<Vt3<Vt4<Vt5<Vt6.

In the illustrated embodiment illustrated in FIGS. 22A-22F, the first high-k gate dielectric layer 50A, the second high-k gate dielectric layer 50B, the third high-k gate dielectric layer 50C, the fourth high-k gate dielectric layer 50D, the fifth high-k gate dielectric layer 50E and the sixth high-k gate dielectric layer 50F include a high-k gate dielectric as mentioned above. In addition to the high-k gate dielectric, the first high-k gate dielectric layer 50A, the second high-k gate dielectric layer 50B, the third high-k gate dielectric layer 50C and the fourth high-k gate dielectric layer 50D also include one of the metal dopants mentioned above (i.e., a Group 2, 3, 4 or 13 metal dopant).

The semiconductor device illustrated in FIGS. 22A-22E can be formed utilizing the basic processing steps of the present application that are described above. In some embodiment, not all of the nanosheet transistors illustrated in FIGS. 22A-22F are formed. In other embodiments, additional nanosheet transistors including high-k gate dielectric layers having other metal dopant concentrations can be formed.

Notably, FIGS. 22A-22D illustrate a semiconductor device in accordance with another embodiment of the present application. The semiconductor device includes a first nanosheet transistor T1 having a first threshold voltage Vt1, and including a first high-k gate dielectric layer 50A having a first metal doping concentration C1; a second nanosheet transistor T2 having a second threshold voltage Vt2, and including a second high-k gate dielectric layer 50B having a second metal doping concentration C2; a third nanosheet transistor T3 having a third threshold voltage Vt3, and including a third high-k gate dielectric layer 50C having a third metal doping concentration C3; and a fourth nanosheet transistor T4 having a fourth threshold voltage Vt4, and including a fourth high-k gate dielectric layer 50D having a fourth metal doping concentration C4. In the illustrated embodiment illustrated in FIGS. 22A-22D, T1 and T3 further include a first nanosheet stack of semiconductor channel material nanosheets 14NS having a first thickness, Tsus1, located beneath a suspended portion of each semiconductor channel material nanosheet 14NS, and T2 and T4 further include a second nanosheet stack of dog-bone shaped nanosheets 15NS having a second thickness, Tsus2, located beneath a suspended portion of each of the dog-bone shaped nanosheets 15NS in which Tsus2 is greater than Tsus1, and C1=C2, C3=C4, and C1 and C2 are greater than C3 and C4. In the illustrated embodiment illustrated in FIGS. 22A-22D, Vt1<Vt2<Vt3<Vt4. By controlling the first and second thicknesses as well as the metal dopant concentration in the metal doped high-k gate dielectric layer. a low capacitance nanosheet containing device is provided in which the nanosheet transistors have multiple threshold voltage.

In some embodiments (see for example, FIGS. 22E and 22F), the semiconductor device further includes a fifth nanosheet transistor T5 having a fifth threshold voltage Vt5, and including a fifth high-k gate dielectric layer 50E; and a sixth nanosheet transistor T6 having a sixth threshold voltage Vt6 and including a sixth high-k gate dielectric layer 50F. In embodiments in which T5 and T6 are present, the fifth high-k gate dielectric layer 50E and the sixth high-k gate dielectric layer 50F are devoid of a metal dopant, and T5 further includes the first nanosheet stack and T6 further includes the second nanosheet stack. In such embodiments, and for the exemplary embodiment illustrated in FIGS. 22A-22F, Vt1<Vt2<Vt3<Vt4<Vt5<Vt6.

In some embodiments and for the exemplary embodiment illustrated in FIGS. 22A-22D, the first high-k gate dielectric layer 50A, the second high-k gate dielectric layer 50B, the third high-k gate dielectric layer 50C and the fourth high-k gate dielectric layer 50D include a high-k gate dielectric and a Group 2 metal. Group 2 metals are used in providing NFETs.

In some embodiments and for the exemplary embodiment illustrated in FIGS. 22A-22D, the first high-k gate dielectric layer 50A, the second high-k gate dielectric layer 50B, the third high-k gate dielectric layer 50C and the fourth high-k gate dielectric layer 50D include a high-k gate dielectric and a Group 3 metal. Group 3 metals are used in providing NFETs.

In some embodiments and for the exemplary embodiment illustrated in FIGS. 22A-22D, the first high-k gate dielectric layer 50A, the second high-k gate dielectric layer 50B, the third high-k gate dielectric layer 50C and the fourth high-k gate dielectric layer 50D include a high-k gate dielectric and a Group 4 metal. Group 4 metals are used in providing PFETs.

In some embodiments and for the exemplary embodiment illustrated in FIGS. 22A-22D, the first high-k gate dielectric layer 50A, the second high-k gate dielectric layer 50B, the third high-k gate dielectric layer 50C and the fourth high-k gate dielectric layer 50D include a high-k gate dielectric and a Group 13 metal. Group 13 metals are used in providing NFETs.

In embodiments and for the exemplary embodiment illustrated in FIGS. 22A-22D, the first nanosheet transistor T1, the second nanosheet transistor T2, the third nanosheet transistor T4 and the fourth nanosheet transistor T4 further include gate electrode 42, in which gate electrode 42 includes a work function metal. Work function metals are used to set threshold voltage of the nanosheet transistors.

In embodiments and for the exemplary embodiment illustrated in FIGS. 22A-22D, the semiconductor device further includes semiconductor substrate 10 located beneath the first nanosheet transistor T1, the second nanosheet transistor T2, the third nanosheet transistor T3 and the fourth nanosheet transistor T4. In such embodiments, each of the first high-k gate dielectric layer 50A, the second high-k gate dielectric layer 50B, the third high-k gate dielectric layer 50C and the fourth high-k gate dielectric layer 50D is present on the semiconductor substrate 10.

In embodiments and for the exemplary embodiment illustrated in FIGS. 22A-22D, the semiconductor device further includes shallow trench isolation structure 16 located in an upper portion of the semiconductor substrate 10. In such embodiments, each of the first high-k gate dielectric layer 50A, the second high-k gate dielectric layer 50B, the third high-k gate dielectric layer 50C and the fourth high-k gate dielectric layer 50D is present on the shallow trench isolation structure 16.

In some embodiments and for the exemplary embodiment illustrated in FIGS. 22A-22F, the first thickness, Tsus1, is equal to or less than 7 nm.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a first nanosheet transistor comprising a first nanosheet stack of semiconductor channel material nanosheets having a first thickness located beneath a suspended portion of each of the semiconductor channel material nanosheets, and a first gate structure comprising a first metal doped high-k gate dielectric layer having a first metal dopant concentration wrapped around the suspended portion of each first semiconductor channel material nanosheet; and
a second nanosheet transistor comprising a second nanosheet stack of dog-bone shaped nanosheets having a second thickness located beneath a suspended portion of each of the dog-bone shaped nanosheets, and a second gate structure comprising a second metal doped high-k gate dielectric layer having a second metal dopant concentration wrapped around the suspended portion of each of the dog-bone shaped nanosheets, wherein the second thickness is greater than the first thickness.

2. The semiconductor device of claim 1, wherein the second metal dopant concentration is less than the first metal dopant concentration.

3. The semiconductor device of claim 1, wherein the second metal dopant concentration is equal to the first metal dopant concentration.

4. The semiconductor device of claim 1, wherein the first nanosheet transistor has a first threshold voltage and the second nanosheet transistor has a second threshold voltage in which second threshold voltage is greater than the first threshold voltage.

5. The semiconductor device of claim 1, wherein the first metal doped high-k gate dielectric layer and the second metal doped high-k gate dielectric layer comprise a Group 2 metal.

6. The semiconductor device of claim 1, wherein the first metal doped high-k gate dielectric layer and the second metal doped high-k gate dielectric layer comprise a Group 3 metal.

7. The semiconductor device of claim 1, wherein the first metal doped high-k gate dielectric layer and the second metal doped high-k gate dielectric layer comprise a Group 4 metal.

8. The semiconductor device of claim 1, wherein the first metal doped high-k gate dielectric layer and the second metal doped high-k gate dielectric layer comprise a Group 13 metal.

9. The semiconductor device of claim 1, wherein the first gate structure and the second gate structure further include a gate electrode, wherein the gate electrode comprises at least a work function metal.

10. The semiconductor device of claim 1, further comprising a semiconductor substrate located beneath the first nanosheet transistor and the second nanosheet transistor, and wherein the first metal doped high-k gate dielectric layer and the second metal doped high-k gate dielectric layer are present on the semiconductor substrate.

11. The semiconductor device of claim 10, further comprises a shallow trench isolation structure located in an upper portion of the semiconductor substrate, and wherein the first metal doped high-k gate dielectric layer and the second metal doped high-k gate dielectric layer are present on the shallow trench isolation structure.

12. The semiconductor device of claim 1, wherein the first thickness is equal to or less than 7 nm.

13. A semiconductor device comprising:
a first nanosheet transistor having a first threshold voltage Vt1, and comprising a first high-k gate dielectric layer having a first metal doping concentration C1;
a second nanosheet transistor having a second threshold voltage Vt2, and comprising a second high-k gate dielectric layer having a second metal doping concentration C2;
a third nanosheet transistor having a third threshold voltage Vt3, and comprising a third high-k gate dielectric layer having a third metal doping concentration C4; and
a fourth nanosheet transistor having a fourth threshold voltage Vt4, and comprising a fourth high-k gate dielectric layer having a fourth metal doping concentration C4, wherein the first nanosheet transistor and the third nanosheet transistor further comprise a first nanosheet stack of semiconductor channel material nanosheets having a first thickness located beneath a suspended portion of each of the semiconductor channel material nanosheets, and the second nanosheet transistor and the fourth nanosheet transistor further comprise a second nanosheet stack of dog-bone shaped nanosheets having a second thickness located beneath a suspended portion of each of the dog-bone shaped nanosheets, wherein the second thickness is greater than the first thickness, C1=C2, C3=C4, and C1 and C2 are greater than C3 and C4, and Vt1<Vt2<Vt3<Vt4.

14. The semiconductor device of claim 13, further comprising:
a fifth nanosheet transistor having a fifth threshold voltage Vt5, and comprising a fifth high-k gate dielectric layer; and
a sixth nanosheet transistor having a sixth threshold voltage Vt6 and comprising a sixth high-k gate dielectric layer, wherein the fifth high-k gate dielectric layer and the sixth high-k gate dielectric layer are devoid of a metal dopant, and the fifth nanosheet transistor further comprises the first nanosheet stack and the sixth nanosheet transistor further comprises the second nanosheet stack and wherein Vt1<Vt2<Vt3<Vt4<Vt5<Vt6.

15. The semiconductor device of claim 13, wherein the first high-k gate dielectric layer, the second high-k gate dielectric layer, the third high-k gate dielectric layer and the fourth high-k gate dielectric layer comprise a high-k gate dielectric and a Group 2 metal.

16. The semiconductor device of claim 13, wherein the first high-k gate dielectric layer, the second high-k gate dielectric layer, the third high-k gate dielectric layer and the fourth high-k gate dielectric layer comprise a high-k gate dielectric and a Group 3 metal.

17. The semiconductor device of claim 13, wherein the first high-k gate dielectric layer, the second high-k gate dielectric layer, the third high-k gate dielectric layer and the fourth high-k gate dielectric layer comprise a high-k gate dielectric and a Group 4 metal.

18. The semiconductor device of claim 13, wherein the first high-k gate dielectric layer, the second high-k gate dielectric layer, the third high-k gate dielectric layer and the fourth high-k gate dielectric layer comprise a high-k gate dielectric and a Group 13 metal.

19. The semiconductor device of claim 13, wherein the first nanosheet transistor, the second nanosheet transistor, the third nanosheet transistor and the fourth nanosheet transistor further comprises a gate electrode, wherein the gate electrode comprises a work function metal.

20. The semiconductor device of claim 13, further comprising a semiconductor substrate located beneath the first nanosheet transistor, the second nanosheet transistor, the third nanosheet transistor and the fourth nanosheet transistor, and wherein each of the first high-k gate dielectric layer, the second high-k gate dielectric layer, the third high-k gate dielectric layer and the fourth high-k gate dielectric layer is present on the semiconductor substrate.

21. The semiconductor device of claim 20, further comprising a shallow trench isolation structure located in an upper portion of the semiconductor substrate, and wherein each of the first high-k gate dielectric layer, the second high-k gate dielectric layer, the third high-k gate dielectric layer and the fourth high-k gate dielectric layer is present on the shallow trench isolation structure.

22. The semiconductor device of claim 13, wherein the first thickness is equal to or less than 7 nm.
